(19) United States
(12) Patent Application Publication
(10) Pub. No.: US 2018/0090311 A1
(43) Pub. Date: Mar. 29, 2018

(54) BORON FILM, BORON FILM FORMING METHOD, HARD MASK, AND HARD MASK MANUFACTURING METHOD

(71) Applicant: TOKYO ELECTRON LIMITED, Tokyo (JP)

(72) Inventors: Takahiro MIYAHARA, Nirasaki City (JP); Kazuo YABE, Nirasaki City (JP); Shigeru NAKAJIMA, Nirasaki City (JP)

(21) Appl. No.: 15/713,109

(22) Filed: Sep. 22, 2017

(30) Foreign Application Priority Data
Sep. 29, 2016 (JP) 2016-190895

(51) Int. Cl. H01L 21/02; H01L 21/3105; H01L 21/3213; H01L 21/033

(52) U.S. Cl. CPC H01L 21/02164; H01L 21/0332; H01L 21/32139; H01L 21/3105

(57) ABSTRACT

There is provided a boron film forming method which includes forming a boron film on a target substrate by CVD by supplying a boron-containing gas as a film-forming source gas to the target substrate while heating the target substrate to a predetermined temperature, the boron film being made of boron and inevitable impurities and used for a semiconductor device.

### CROSS-REFERENCE TO RELATED APPLICATION

This application is based upon and claims the benefit of priority from Japanese Patent Application No. 2016-190895, filed on Sep. 29, 2016, the entire contents of which are incorporated herein by reference.

### TECHNICAL FIELD

The present disclosure relates to a boron film used for a semiconductor device, a boron film forming method, a hard mask using the boron film, and a hard mask manufacturing method.

### BACKGROUND

In a semiconductor device, a boron-based film containing boron as a main component is used. The boron-based film has various excellent characteristics such as a high etching resistance, a low dielectric constant and the like. Applications of the boron-based film to various uses have been studied.

For example, there is known a boron-based film applied to a hard mask when etching a boron nitride film.

However, a boron film as the boron-based film is hardly applied to a semiconductor device despite the fact that the boron film is a film having various possibilities.

### SUMMARY

Some embodiments of the present disclosure provide a boron film effective when applied to a semiconductor device, a method of forming the boron film, and a practical application thereof.

According to one embodiment of the present disclosure, there is provided a boron film made of boron and inevitable impurities and used for a semiconductor device.

According to another embodiment of the present disclosure, there is provided a boron film forming method which includes: forming a boron film on a target substrate by CVD by supplying a boron-containing gas as a film-forming source gas to the target substrate while heating the target substrate to a predetermined temperature.

According to another embodiment of the present disclosure, there is provided a hard mask including the aforementioned boron film, wherein the hard mask is used as an etching mask when a recess is formed by etching a film including a SiO₂ film formed on a target substrate.

According to another embodiment of the present disclosure, there is provided a hard mask manufacturing method, which includes: forming a boron film by the aforementioned film forming method using a substrate having a film including a SiO₂ film; and forming a hard mask used when a recess is formed by etching the film including the SiO₂ film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional view showing an example of a film forming apparatus for carrying out a boron film forming method.

FIG. 2 is a timing chart showing an example of a sequence of a boron film forming method.

FIG. 3 is a diagram showing a relationship between a film formation time and a film thickness when a boron film is formed in the sequence of FIG. 2 using the apparatus of FIG. 1.

FIG. 4 is a diagram showing an atomic concentration of each element in a depth direction of a film measured by XPS when a boron film is formed in the sequence of FIG. 2 using the apparatus of FIG. 1.

FIGS. 5A and 5B are views showing a state in which a conventional hard mask is formed when etching a laminated film including a SiO₂ film, and a state in which a trench having a depth of 1 to 5 μm is formed using a hard mask as a mask.

FIG. 6 is a diagram showing a selectivity of a SiO₂ film to each film when a trench etching is performed wider DRAM conditions.

FIG. 7 is a diagram showing a selectivity of a SiO₂ film to each film when a trench etching is performed under NAND conditions.

FIGS. 8A and 8B are views showing a state in which a hard mask made of a boron film is formed when etching a laminated film including a SiO₂ film, and a state in which a trench having a depth of 1 to 5 μm is formed using a hard mask as a mask.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Boron Film>

A boron film according to the present embodiment is made of boron and inevitable impurities. This boron film is typically a CVD film. The inevitable impurities include hydrogen (H), oxygen (O), carbon (C) and the like depending on a raw material.

### <Boron Film Forming Method>

Such a boron film is formed by CVD according to the following sequence. A substrate to be processed, for example, a semiconductor wafer is accommodated in a predetermined process container. The inside of the process container is brought into a vacuum state with a predetermined pressure. The substrate to be processed is heated to a predetermined temperature. In this state, a boron-containing gas as a film-forming source gas is supplied into the process container. The boron-containing gas is pyrolized on the substrate to be processed. Thus, the boron film is formed on the substrate to be processed.

Examples of the boron-containing gas include a diborane (B₂H₆) gas, a boron trichloride (BCl₃) gas, an alkylborane-based gas, an aminoborane-based gas and the like. Examples of the alkylborane-based gas include a trimethylborane (B(CH₃)₃) gas, a triethylborane (B(C₂H₅)₃) gas, gases denoted by B(R1)(R2)(R3), B(R1)(R2)H and B(R1)H₂ (where R1, R2 and R3 are alkyl groups), and the like. Examples of the aminoborane-based gas include an aminoborane (NH₂BH₂) gas, a tris(dimethylamino)borane (B(N(CH₃)₂)₃) gas and the like.

The temperature at the time of forming the boron film by CVD may fall within a range of to be in a range of 200 to 500 degrees C. When the boron-containing gas is a B₂H₆ gas, the temperature may fall within a range of 200 to 300 degrees C. The internal pressure of the process container at this time may fall within a range of 13.33 to 1,333 Pa (0.1 to 10 Torr).

### [One Example of Film Forming Apparatus]

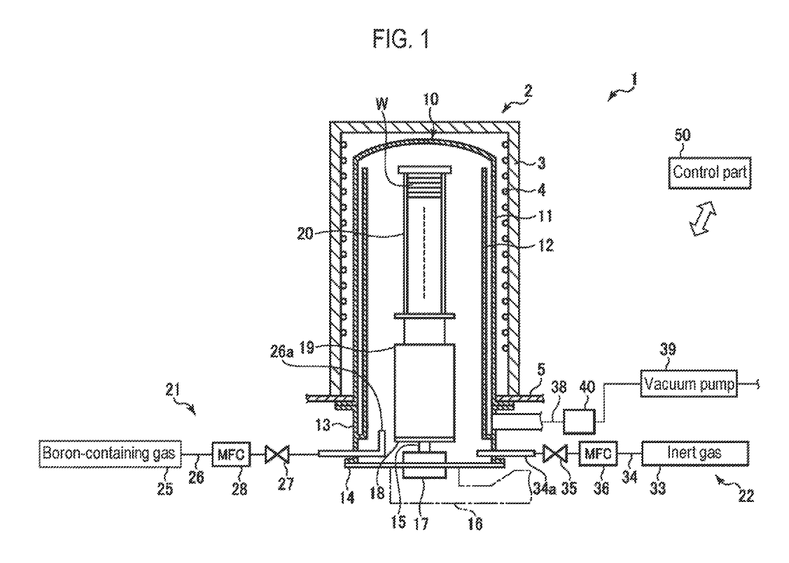

FIG. 1 is a vertical sectional view showing an example of a film forming apparatus for carrying out the boron film forming method described above.

The film forming apparatus 1 is configured as a batch type processing apparatus capable of processing a plurality of, for example, 50 to 150 substrates at a time. The film forming apparatus 1 is provided with a heating furnace 2 that includes a tubular heat insulator 3 having a ceiling portion, and a heater 4 installed on the inner peripheral surface of the heat insulator 3. The heating furnace 2 is installed on a base plate 5.

Inside the heating furnace 2, there is inserted a process container 10 of a double tube structure that includes an outer tube 11 made of, for example, quartz and closed at the upper end thereof, and an inner tube 12 concentrically disposed inside the outer tube 11 and made of, for example, quartz. The heater 4 is installed so as to surround the outside of the process container 10.

The outer tube 11 and the inner tube 12 are respectively held at lower ends thereof by a tubular manifold 13 made of stainless steel or the like. At a lower end opening of the manifold 13, a cap part 14 for airtightly sealing the lower end opening is installed in an openable/closeable manner.

A rotary shaft 15 which is rotatable in an airtight state by, for example, a magnetic seal, is inserted in the central portion of the cap part 14. A lower end of the rotary shaft 15 is connected to a rotating mechanism 17 of an elevating table 16. An upper end of the rotary shaft 15 is fixed to a turntable 18. A quartz-made wafer boat 20 for holding semiconductor wafers (hereinafter simply referred to as “wafers”) as substrates to be processed is mounted on the turntable 18 via a heat insulating tube 19. The wafer boat 20 is configured to accommodate, for example, 50 to 150 wafers W stacked at a predetermined pitch.

The wafer boat 20 can be loaded into and unloaded from the process container 10 by raising and lowering the elevating table 16 with an elevating mechanism (not shown). When the wafer boat 20 is loaded into the process container 10, the cap part 14 is brought into close contact with the manifold 13 so that the interior of the process container 10 is air-tightly sealed.

Further, the film forming apparatus 1 includes a film-forming source gas supply mechanism 21 for introducing a boron-containing gas which is a film-forming source gas, for example, a B₂H₆ gas, into the process container 10, and an inert gas supply mechanism 22 for introducing an inert gas used as a purge gas or the like into the process container 10.

The film-forming source gas supply mechanism 21 includes a boron-containing gas supply source 25 for supplying a boron-containing gas, for example, a B₂H₆ gas, as a film-forming source gas, a film-forming gas pipe 26 for introducing a film-forming gas from the boron-containing gas supply source 25 therethrough, and a quartz-made film-forming gas nozzle 26a connected to the film-forming gas pipe 26 and installed so as to penetrate the lower portion of the side wall of the manifold 13. In the film-forming gas pipe 26, an opening/closing valve 27 and a flow rate controller 28 such as a mass flow controller or the like are installed so as to supply the film-forming gas while controlling the flow rate thereof.

The inert gas supply mechanism 22 includes an inert gas supply source 33, an inert gas pipe 34 for introducing an inert gas from the inert gas supply source 33 therethrough, and an inert gas nozzle 34a connected to the inert gas pipe 34 and installed so as to penetrate the lower portion of the side wall of the manifold 13. In the inert gas pipe 34, there are installed an opening/closing valve 35 and a flow rate controller 36 such as a mass flow controller or the like. As the inert gas, it may be possible to use an N₂ gas or a noble gas such as an Ar gas or the like.

An exhaust pipe 38 for discharging a process gas from a gap between the outer pipe 11 and the inner pipe 12 therethrough is connected to the upper portion of the side wall of the manifold 13. The exhaust pipe 38 is connected to a vacuum pump 39 for evacuating the interior of the process container 10. A pressure regulating mechanism 40 including a pressure regulating valve and the like is installed in the exhaust pipe 38. While evacuating the interior of the process container 10 with the vacuum pump 39, the internal pressure of the process container 10 is regulated to a predetermined pressure by the pressure regulating mechanism 40.

The film forming apparatus 1 includes a control part 50. The control part 50 includes a main control part having a computer (CPU) for controlling respective constituent parts of the film forming apparatus 1, for example, the valves, the mass flow controllers, a heater power supply, the elevating mechanism and the like, an input device, an output device, a display device and a memory device. Parameters of various processes to be executed by the film forming apparatus 1 are stored in the memory device. A storage medium which stores programs, i.e., process recipes for controlling the processes executed in the film forming apparatus 1 is set in the memory device. The main control part calls out a predetermined process recipe stored in the storage medium and executes control so that a predetermined process is performed by the film forming apparatus 1 based on the predetermined process recipe.

In the film forming apparatus 1 configured as above, the boron film forming method according to the above-described embodiment is carried out under the control of the control part 50.

### [Film Forming Sequence]

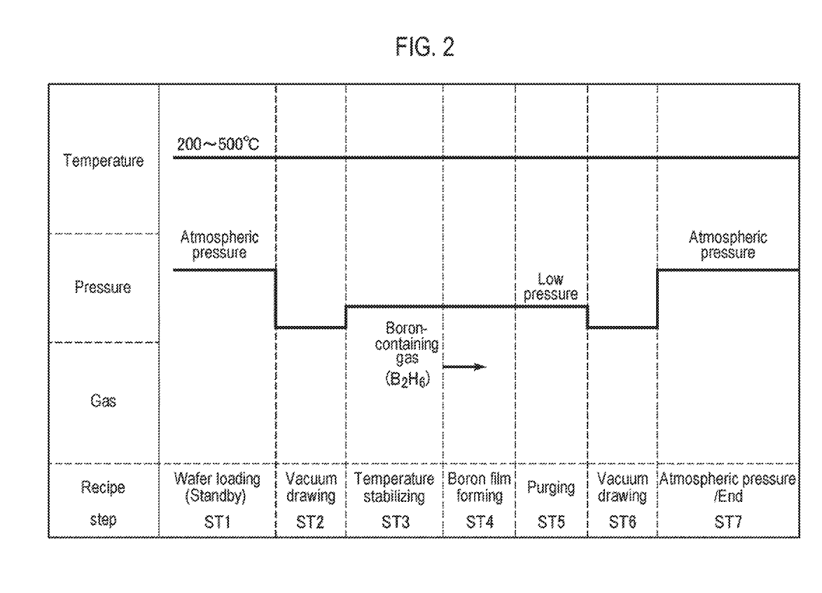

An example of the sequence at this time will be described with reference to FIG. 2. FIG. 2 is a timing chart at the time of forming a boron film by the film forming apparatus 1 of FIG. 1, showing a temperature, a pressure, an introduced gas and recipe steps.

In the example of FIG. 2, first, the interior of the process container 10 is controlled to have a temperature of 200 to 500 degrees C., and the wafer boat 20 holding a plurality of wafers W is loaded into the process container 10 under the atmospheric pressure (ST1). An evacuation process is performed in this state to bring the interior of the process container 10 into a vacuum state (ST2). Subsequently, the interior of the process container 10 is regulated to have a predetermined low pressure, for example, 133.3 Pa (1.0 Torr), and the temperature of the wafers W is stabilized (ST3). In this state, a boron-containing gas such as a B₂H₆ gas or the like is introduced into the process container 10 by the film-forming source gas supply mechanism 21, and a boron film is formed on the surface of the wafer W by CVD which thermally decomposes the boron-containing gas on the surface of the wafer W (ST4). Thereafter, an inert gas is supplied from the inert gas supply mechanism 22 into the process container 10 to purge the interior of the process container 10 (ST5). The interior of the process container 10 is subsequently evacuated by the vacuum pump 39 (ST6). Thereafter, the internal pressure of the process container 10 is restored to the atmospheric pressure, and the process is terminated (ST7). When the boron-containing gas is a B₂H₆ gas, the internal temperature of the process container 10 may be controlled to fall within a range of 200 to 300 degrees C.

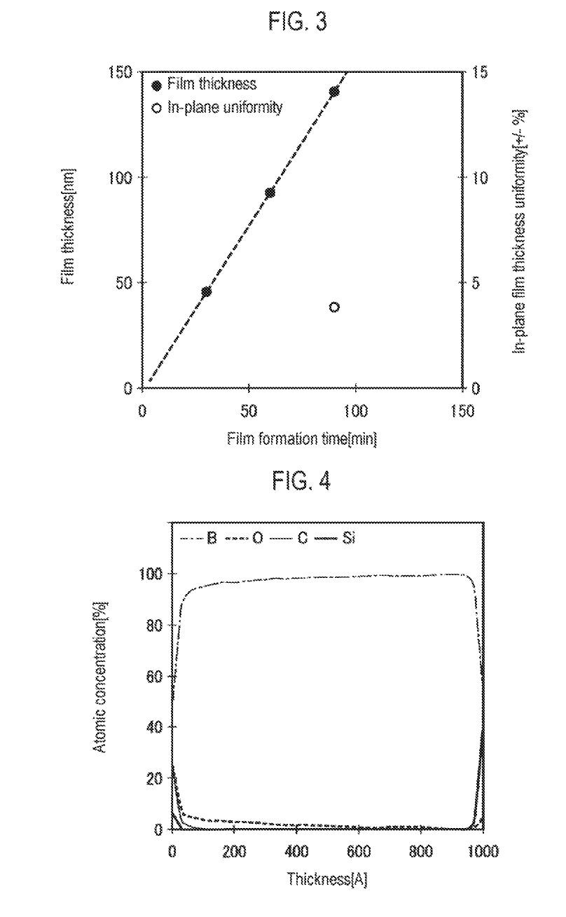

The relationship between the actual film formation time and the film thickness at this time is as shown in FIG. 3. It was confirmed that a practical deposition rate is obtained. In FIG. 3, there is also shown the wafer in-plane uniformity. The in-plane uniformity was about 4% at the film formation time of about 90 min.

In addition, the profile of respective elements in the depth direction of the actually formed film at this time measured by an XPS is as shown in FIG. 4. It was confirmed that a boron film with little impurities is obtained. Although the XPS cannot detect hydrogen, in reality, the film contains a small amount of hydrogen.

### <Properties and Applications of Boron Film>

It was found that the boron film described above has a high resistance to dry etching of a silicon oxide film (SiO₂ film) so that a film including a SiO₂ film can be etched with a high selectivity to the boron film. Therefore, it was newly discovered that a hard mask for etching a SiO₂ film is promising as an application of the boron film.

In recent years, with the progress of a 3D structuring and miniaturizing technique of a semiconductor device, it is necessary to form a trench having a depth of as much as a few μm by dry etching. At the same time, there is a need to reduce an etching width to about several tens of nm as far as possible. However, an organic resist material, amorphous carbon (a-C) and amorphous silicon (a-Si), which are conventionally used as a hard mask in such dry etching, have insufficient selectivity with a SiO₂ film. When etching is performed deeply in the vertical direction, etching gradually progresses in the lateral direction little by little. As a result, the width of a trench increases.

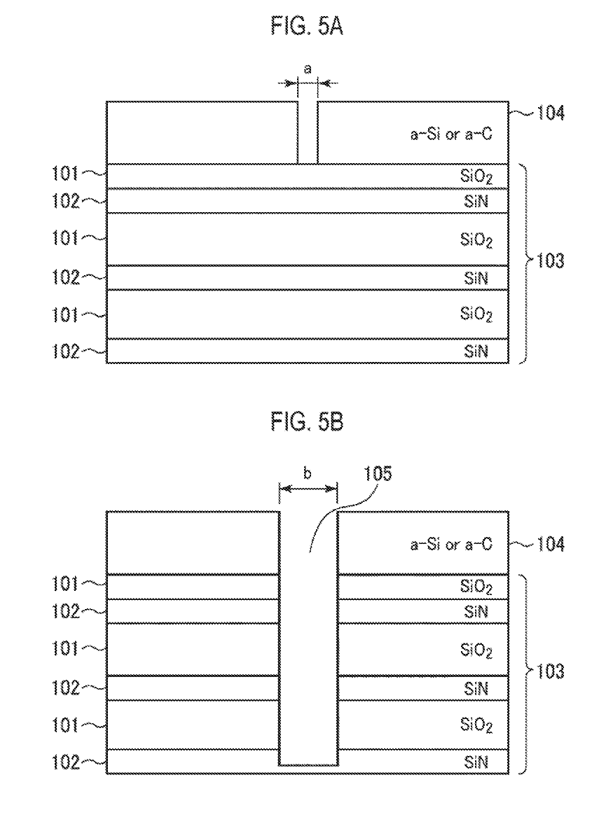

For example, in a manufacturing process of a 3D device, as shown in FIG. 5A, a laminated film 103 having a thickness of about 1 to 5 μm, which is formed by repeatedly laminating a SiO₂ film 101 and a SiN film 102 plural times is etched in the depth direction to form a trench. For the purpose of etching, a hard mask corresponding to the depth of a trench is formed. For example, when an amorphous silicon (a-Si) film or an amorphous carbon (a-C) film 104 is used as a hard mask, as shown in FIG. 5B, the width b of a trench 105 formed by the etching is considerably wider than the initial opening width a of the amorphous silicon (a-Si) film or the amorphous carbon (a-C) film 104 formed as a hard mask.

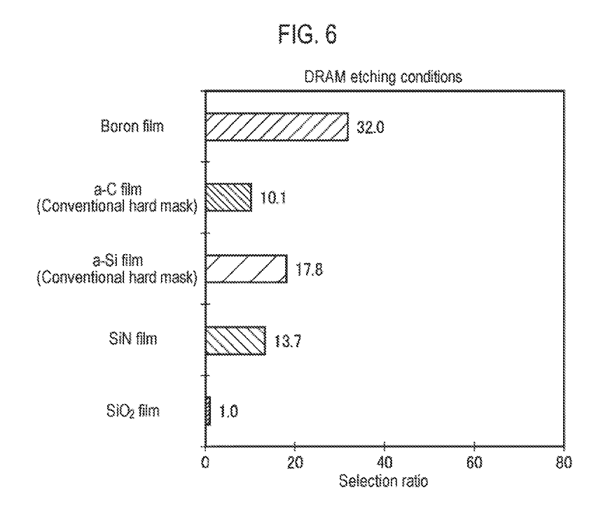

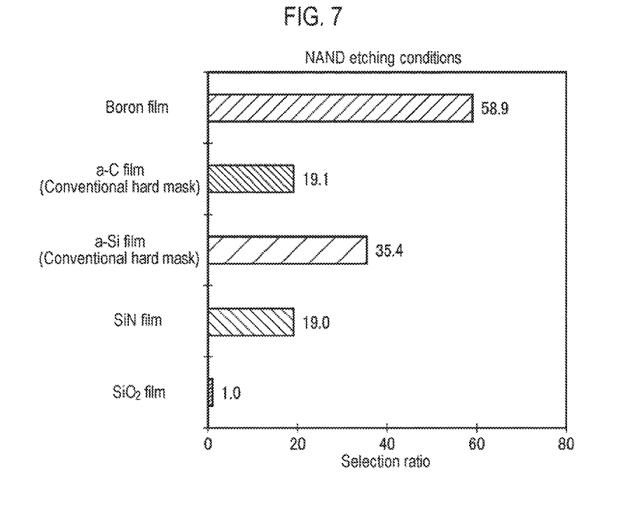

On the other hand, the boron film is more resistant to the SiO₂ film etching conditions (dry etching conditions) than the conventional a-C film and the conventional a-Si film. As shown in FIGS. 6 and 7, under the DRAM etching conditions and the NAND etching conditions, the selectivity of the SiO₂ film to the boron film are 32.0 and 58.9, respectively, and are relatively high, as compared with the fact that the selectivity to the a-C film used as a conventional hard mask material are 10.1 and 19.1, respectively, and the selectivity to the a-Si film are 17.8 and 35.4, respectively. That is to say, it can be understood that, under the SiO₂ film etching conditions, the boron film has a higher etching resistance than the a-Si film or the a-C film which is a conventional hard mask material.

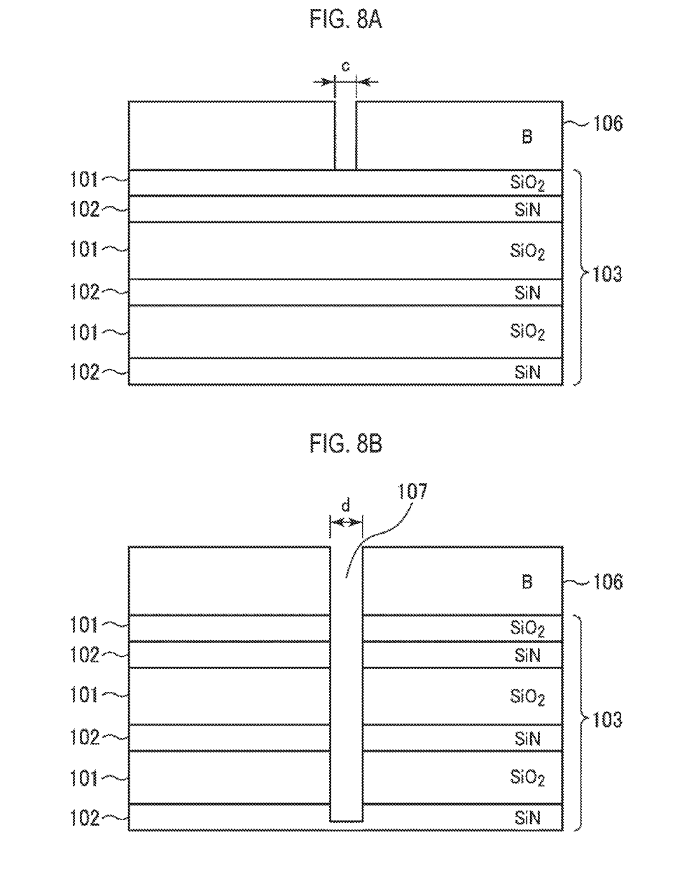

Therefore, as shown in FIG. 8A, when etching is performed using a boron film 106 as a hard mask, as shown in FIG. 8B, etching in the lateral direction is suppressed, which restrains the width d of a trench 107 from increasing from the initial opening width c of the boron film. Since the SiO₂ film 101 and the like can be etched with a high selectivity, it is possible to reduce the thickness of the boron film 106 as a hard mask.

The hard mask using the boron film of the present embodiment is suitable when forming a recess such as a trench or the like by etching a film including a SiO₂ film, and is more suitable particularly when the depth of the recess is 500 nm or more, especially 1 μm or more.

When the boron film is applied as a hard mask, the surface of the boron film may be processed with Ar plasma or H₂ plasma to form a plasma-modified layer on the surface of the boron film. As a result, boron-boron bonding on the film surface is promoted, and a hard mask with high strength is obtained.

In addition, the boron film has a property of being easily oxidized. The property of the boron film is changed by oxidation. Therefore, if the boron film is exposed to a plasma oxidizing atmosphere by, for example, forming a TEOS film on the boron film by plasma CVD, there is a concern that the performance of the boron film is deteriorated due to the oxidation of the boron film. In such a case, a protective layer having a high oxidation resistance may be formed on the surface of the boron film. As such a protective layer, a SiN film, a SiC film, a SiCN film, an a-Si film or the like may be suitably used.

### <Other Applications>

While the embodiments of the present disclosure have been described above, the present disclosure is not limited to the above-described embodiments. Various modifications may be made without departing from the spirit of the present disclosure.

For example, in the above embodiments, the hard mask has been illustrated as an application of the boron film. However, the application of the boron film is not limited thereto and may be applied to other applications such as a diffusion-preventing barrier film in a thin film application.

In the above embodiments, the vertical batch type apparatus has been described as an example of the film forming apparatus for forming the boron film. However, other various film forming apparatuses such as a horizontal batch type apparatus and a single-wafer-type apparatus may be used. When a plasma process is performed on the surface of the boron film, it is preferable to use a single-wafer-type apparatus because the plasma process can be performed directly after film formation by using the single-wafer-type apparatus.

According to the present disclosure in some embodiments, it is possible to provide a boron film effective when applied to a semiconductor device, a method of forming the boron film, and a practical application thereof.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A boron film made of boron and inevitable impurities and used for a semiconductor device.

2. The boron film of claim 1, wherein the boron film is a CVD film.

3. The boron film of claim 1, wherein the boron film is used as a hard mask when a recess is formed by etching a film including a SiO₂ film.

4. A boron film forming method, comprising:
forming a boron film on a target substrate by CVD by supplying a boron-containing gas as a film-forming source gas to the target substrate while heating the target substrate to a predetermined temperature.

5. The method of claim 4, wherein the boron-containing gas is at least one selected from a group consisting of a diborane gas, a boron trichloride gas, an alkylborane gas and an aminoborane gas.

6. The method of claim 4, wherein the temperature of the target substrate is 200 to 500 degrees C.

7. The method of claim 4, wherein the boron film is formed by thermally decomposing the boron-containing gas on the target substrate.

8. The method of claim 4, wherein the target substrate includes a film including a SiO₂ film, and the boron film is formed on the film including the SiO₂ film as a hard mask for forming a recess by etching the film including the SiO₂ film.

9. A hard mask, comprising:
the boron film of claim 1,
wherein the hard mask is used as an etching mask when a recess is formed by etching a film including a SiO₂ film formed on a target substrate.

10. The hard mask of claim 9, wherein a plasma-modified layer modified by an Ar plasma or an H₂ plasma is formed on a surface of the boron film.

11. The hard mask of claim 9, wherein a protective film for suppressing an oxidation of boron is formed on a surface of the boron film.

12. A hard mask manufacturing method, comprising:
forming a boron film by the method of claim 4 using a substrate having a film including a SiO₂ film; and
forming a hard mask used when a recess is formed by etching the film including the SiO₂ film.

13. The method of claim 12, wherein a plasma process using an Ar plasma or an H₂ plasma is performed on a surface of the boron film.

14. The method of claim 12, wherein a protective film for suppressing an oxidation of boron is formed on a surface of the boron film.
